(19) United States
(12) Patent Application Publication
(10) Pub. No.: US 2005/0110502 A1
(43) Pub. Date: May 26, 2005

(54) System and method for determining S-parameters

(76) Inventors: Yong Wang, Fort Collins, CO (US); Karl Bois, Fort Collins, CO (US); David W. Quint, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/701,864

(22) Filed: Nov. 5, 2003

(51) Int. Cl. G01R 15/00

(52) U.S. Cl. 324/601

(57) ABSTRACT

A system for determining S-parameters of a network includes an S-parameter calculator that computes the S-parameters of the network based on waveform parameters determined through single port measurements at each of plural ports of the network.

### RELATED APPLICATION

This application is related to co-pending and commonly assigned U.S. patent application to Yang et al., which was filed contemporaneously with this application and entitled “SYSTEM AND METHOD FOR DETERMINING S-PARAMETERS USING A MATCHED LOAD,” Attorney Docket No. 200314668-1, the disclosure of which is incorporated herein by reference.

### BACKGROUND

Electronic networks, such as integrated circuits (ICs), are employed to perform a variety of electronic functions, such as filtering microwave or radio frequency signals. In evaluating the performance of a particular network, it may be desirable to measure its electrical accuracy. One manner by which the electrical accuracy of a network can be measured is by determining the scattering parameters (S-parameters) of the network. The S-parameters of a network are indicative of the degree of signal transmission and reflection at the ports of the network.

Typically, to determine the S-parameters of a network, an analysis tool, such as a network analyzer, is used to measure waveform parameters simultaneously at the input and output ports of the network. For example, to measure the waveform parameters at the ports of the network, probes can be utilized to establish electrical contact between the ports and the network analyzer. Establishing electrical contact with probes, however, can be problematic in that the ports of the network may be electrically conductive pads that may be extremely small, such as having a pitch of 250 microns or less. This issue can become compounded in a network having pads located on opposite surfaces of an IC die, package substrate or printed circuit board. Accordingly, to establish a clean and reliable connection with the pads usually requires a high degree of precision.

### SUMMARY

According to one embodiment of the present invention, a system for determining S-parameters of a network includes an S-parameter calculator that computes the S-parameters of the network based on waveform parameters determined through single port measurements at each of plural ports of the network.

According to another embodiment of the present invention, a system for determining S-parameters of a multi-port network includes a reflection coefficient engine that provides a subset of available reflection coefficients associated with ports of the multi-port network. The system also includes an S-parameter calculator that computes a set of the S-parameters for the multi-port network based on the subset available reflection coefficients provided by the reflection coefficient engine.

According to yet another embodiment of the present invention, a method for determining S-parameters of a network includes determining waveform parameters based on single port measurements performed at plural ports of the network, and determining S-parameters of the network based on the waveform parameters.

According to still another embodiment of the present invention, a computer-readable medium having computer-executable instructions can receive waveform parameters based on single port measurements performed at plural ports of the network, and determine S-parameters of the network based on the waveform parameters.

According to another embodiment of the present invention, a computer-readable medium having computer-executable instructions can determine reflection coefficients based on single port measurements performed at ports of the network, and determine S-parameters of the network based on the reflection coefficients.

### BRIEF DESCRIPTION OF THE DRAWINGS

FIG. 1 depicts a simplified block diagram of a circuit including a network in accordance with an embodiment of the present invention.

FIG. 2 depicts a simplified block diagram of a system in a first configuration for determining S-parameters of a network in accordance with an embodiment of the present invention.

FIG. 3 depicts a simplified block diagram of the system of FIG. 2 in a second configuration for determining S-parameters of a network in accordance with an embodiment of the present invention.

FIG. 4 depicts a simplified block diagram of a system for determining S-parameters of a network in accordance with an embodiment of the present invention.

FIG. 5 depicts a flow diagram illustrating a methodology for determining S-parameters of a network in accordance with an embodiment of the present invention.

FIG. 6 depicts a flow diagram illustrating another method.

### DETAILED DESCRIPTION

The present disclosure relates generally to a system and method for determining S-parameters for an electronic network, which can have two or more ports. A set of reflection coefficients are derived for the network based on waveform parameters. The waveform parameters, for example, can be measured by a network analyzer or other test equipment using single port measurements (e.g., measure parameters at one port while the other port(s) is either open or shorted). The S-parameters of the network can be determined from a subset of the reflection coefficients. According to one embodiment of the present invention, the S-parameters are determined based on those coefficients derived from single port measurements of the network.

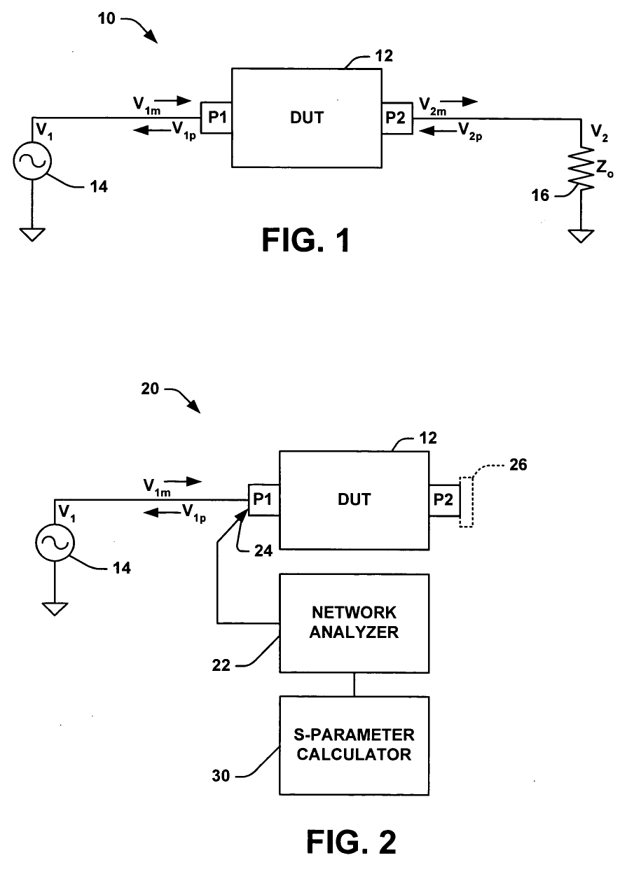

FIG. 1 illustrates a circuit 10 including a device under test (DUT) 12. In the example of FIG. 1, the DUT 12 is assumed to be a passive two-port electronic network. As such, the DUT 12 can be characterized by four S-parameters S₁₁, S₁₂, S₂₁, and S₂₂. The S-parameters can be determined based on reflection coefficients determined for the DUT 12. According to an aspect of the present invention, reflection coefficients “Γ” for the DUT 12 can be determined based on single port measurements of waveform parameters of the DUT. For example, the waveform parameters can be measured at a particular single port, such as when the other port(s) are either left open or are shorted. The single port measurements are particularly useful when the ports may be located on substantially opposing surface of the DUT 12, such as opposite sides of an IC die, package substrate or printed circuit board. The reflection coefficients may then be used to determine the S-parameters of the DUT 12, such as by reconstructing an S-parameter matrix (or model) that characterizes the DUT.

In characterizing the DUT 12, the S₁₁parameter is related to signal reflection at the input port P1, which is a function of the input impedance of the DUT, and models how the DUT reflects the input signal V₁. The S₂₂ parameter of the DUT 12 is related to signal reflection at the output port P2, which is a function of the output impedance of the DUT in relation to the impedance of the load Z₀, and models signal reflection at the output port P2. The S₁₂ parameter models the reverse gain of the DUT 12. The S₂₁parameter is the insertion or forward gain of the DUT 12.

To illustrate operation of the circuit 10, it can include a source 14 that supplies an input signal (e.g., a sine wave at a desired frequency) having a voltage V₁ to an input port P1 of the DUT 12. An output port P2 of the DUT 12 provides an output signal V₂ based on the input signal V₁. In the example of FIG. 1, the DUT 12 provides the output signal V₂ to a load 16 having a characteristic impedance Z₀, such as about 50 ohms.

Waveform parameters (e.g., amplitude or voltage) of the DUT 12 can be measured at the input port P1 and at the output port P2. The waveform parameters include the transmitted portion V₁ₘ of the input signal V₁, i.e., the portion of the input signal V₁ transmitted to the DUT 12 from the source 14. The waveform parameters also include the reflected portion V₁ₚof the input signal V₁, i.e., the portion of the input signal V₁ reflected back toward the source 14 from the DUT. The waveform parameters can also include the transmitted portion V₂ₘ of the output signal V₂, i.e., the portion of the output signal V₂ transmitted to the load Z₀ from the DUT 12, and the reflected portion V₂ₚ of the output signal V₂, i.e., the portion of the output signal reflected back toward the DUT from the load Z₀.

The amplitude of V₁ₚ depends on the amount of mismatch between the output impedance of the source 14 and the input impedance of the DUT 12. The amplitude of V₁ₚ increases according to the mismatch between the output impedance of the source 14 and the input impedance of the DUT 12. If the input impedance of the DUT 12 and the output impedance of the source 14 are matched and the output impedance and the load Z₀ are matched, for example, there will be no reflection of the input signal V₁, namely, V₁ₚ=0 and V₁ₘ=V₁/2, assuming the source 14 has a 50 Ohm series resistance.

Similarly, the amplitude of V₂ₚ depends on the amount of mismatch between the output impedance of the DUT 12 and the impedance of the load Z₀. The amplitude of V₂ₚ increases with the mismatch between the output impedance of the DUT 12 and the impedance of the load Z₀. If the impedance of the load Z₀ and the output impedance of the DUT 12 are matched and the input impedance and the output impedance of the source 14 are matched, there will be no reflection of the output signal V₂, namely, V₂ₚ=0 and V₂ₘ=V₂/2, assuming the source 14 has a 50 Ohm series resistance.

The S-parameters of the DUT 12 are related to waveform parameters V₁ₘ, V₁ₚ, V₂ₘ, and V₂ₚ, which, for a two port network, can be expressed as follows:

$$( \begin{matrix}{V}_{1 m} \\ {V}_{2 m}\end{matrix} ) = ( \begin{matrix}{S}_{11} {S}_{12} \\ {S}_{21} {S}_{22}\end{matrix} ) \cdot ( \begin{matrix}{V}_{1 p} \\ {V}_{2 p}\end{matrix} ) \qquad Eq . 1$$

According to an aspect of the present invention, reflection coefficients Γ for the DUT 12 can be determined through single port measurements of waveform parameters of the DUT. The reflection coefficients may then be used to determine the S-parameters of the DUT 12 and reconstruct the S-parameter matrix of Eq. 1. As mentioned above, the waveform parameters are measured at one particular port, such as while the other port(s) are either left open or are shorted.

The following sets forth an example derivation of equations that can be employed to determine the reflection coefficients and the S-parameters through single port measurements:

If the output port P2 is left open, V₂ₘ=V₂ₚ. This being the case, the S-parameter matrix of Eq. 1 may be reduced to the following:
V₁ₘ=S₁₁·V₁ₚ+S₁₂·V₂ₚ Eq. 2
V₂ₚ=S₂₁·V₁ₚ+S₂₂·V₂ₚ Eq. 3

V₂ₚ may be solved as a function of V₁ₚ and Eq. 3 can be rewritten as follows:

$${V}_{2 p} = {S}_{21} \cdot \frac{{V}_{1 p}}{( 1 - {S}_{22} )} \qquad Eq . 4$$

Eq. 4 can be substituted in Eq. 2 and Eq. 2 can be rewritten as follows:

$${V}_{1 m} = {S}_{11} \cdot {V}_{1 p} + {S}_{12} \cdot {S}_{21} \cdot \frac{{V}_{1 p}}{( 1 - {S}_{22} )} \qquad Eq . 5$$

Eq. 5 can be rewritten to express a reflection coefficient (Γ₂ₒₚₑₙ) that represents a ratio of transmission to reflection for the open condition of the output port P2 as follows:

$$\frac{{V}_{1 m}}{{V}_{1 p}} = {Γ}_{2 open} = {S}_{11} + \frac{{S}_{12} \cdot {S}_{21}}{( 1 - {S}_{22} )} \qquad Eq . 6$$

If the output port P2 is shorted, V₂ₘ=−V₂ₚ. In the shorted condition of the output port P2, the S-parameter matrix of Eq. 1 may be reduced to the following:

$$\begin{matrix}{V}_{1 m} = {S}_{11} \cdot {V}_{1 p} + {S}_{12} \cdot {V}_{2 p} & Eq . 7 \\ - {V}_{2 p} = {S}_{21} \cdot {V}_{1 p} + {S}_{22} \cdot {V}_{2 p} & Eq . 8\end{matrix}$$

V₂ₚ may be solved as a function of V₁ₚ and Eq. 8 can be rewritten as follows:

$${V}_{2 p} = - {S}_{21} \cdot \frac{{V}_{1 p}}{( 1 + {S}_{22} )} \qquad Eq . 9$$

Eq. 9 can be substituted in Eq. 7 to provide:

$${V}_{1 m} = {S}_{11} \cdot {V}_{1 p} - {S}_{12} \cdot {S}_{21} \cdot \frac{{V}_{1 p}}{( 1 + {S}_{22} )} \qquad Eq . 10$$

Eq. 10 further can be rewritten to express a reflection coefficient (Γ₂ₛₕₒᵣₜ), which represents a ratio of transmission to reflecttion for the shorted condition of the output port P2. Γ₂ₛₕₒᵣₜ can be expressed as follows:

$$\frac{{V}_{1 m}}{{V}_{1 p}} = {Γ}_{2 short} = {S}_{11} - \frac{{S}_{12} \cdot {S}_{21}}{( 1 + {S}_{22} )} \qquad Eq . 11$$

If the input port P1 is left open, V₂ₘ=V₂ₚ. An equation for determining the reflection coefficient with the input port P1 open could be derived in a manner similar to the derivation of Eq. 6, described above. The equations describing the DUT 12 simplify since the DUT in the example of FIG. 1 is be a passive device. By “passive,” it is meant that the network adds substantially no gain to the input signal V₁ and, therefore, S₁₂=S₂₁. Because the DUT 12 is a passive device, symmetry permits an equation expressing a reflection coefficient (Γ₁ₒₚₑₙ), as a ratio of transmission to reflection for the open port condition of the input port P1. Thus, the equation for expressing Γ₁ₒₚₑₙ can be extrapolated from Eq. 6 to provide:

$$\frac{{V}_{2 m}}{{V}_{2 p}} = {Γ}_{1 open} = {S}_{22} + \frac{{S}_{12} \cdot {S}_{21}}{( 1 - {S}_{11} )} \qquad Eq . 12$$

If the output port P2 is shorted, V₁ₘ=−V₁ₚ. An equation for determining the reflection coefficient (Γ₁ₛₕₒᵣₜ) which is a ratio of transmission to reflection, for the shorted condition of the input port P1 can be derived in a manner similar to the derivation of Eq. 11, described above. Since the DUT 12 is a passive device, as mentioned above, symmetry permits the following equation (Eq. 13) to be extrapolated from Eq. 11, as follows:

$$\frac{{V}_{2 m}}{{V}_{2 p}} = {Γ}_{1 short} = {S}_{22} - \frac{{S}_{12} \cdot {S}_{21}}{( 1 + {S}_{11} )} \qquad Eq . 13$$

Additionally, since the DUT 12 is a passive two-port network, there is no forward or reverse gain, such that S₁₂=S₂₁. Therefore, for a two port network having the S-parameters S₁₁, S₁₂, S₂₁, and S₂₂, any three unknown S-parameters can be employed to solve for the remaining S-parameter. That is, only three of the four Eqs. 6, 11, 12, and 13 are required to calculate the S-parameters of the DUT 12. Thus, it will be appreciated that the S-parameters of the two-port DUT 12 can be determined based on a subset of three of the four single port measurements described above. That is, the complete S-parameter model for the DUT 12 can be computed by employing any three of the four reflection coefficients Γ₁ₒₚₑₙ, Γ₁ₛₕₒᵣₜ, Γ₂ₒₚₑₙ, and Γ₂ₛₕₒᵣₜ derived from such single port measurements.

By way of further example, the following illustrates the derivation of equations for determining S-parameters using three of the four determined reflection coefficients, namely Γ₁ₒₚₑₙ, Γ₂ₒₚₑₙ, and Γ₂ₛₕₒᵣₜ. For instance, Eqs. 6, 11, and 12 are used to solve the S-parameter matrix of Eq. 1 for each of the S-parameters S₁₁, S₁₂, S21, and S₂₂. It will be appreciated, however, that any three of the four reflection coefficients Γ₁ₒₚₑₙ, Γ₁ₛₕₒᵣₜ, Γ₂ₒₚₑₙ, and Γ₂ₛₕₒᵣₜ and, thus, any corresponding three of Eqs. 6, 11, 12, and 13, could be used to solve the S-parameter matrix of Eq. 1. Similarly, it will be appreciated that the S-parameters can be determined using different combinations of three reflection coefficients, which could allow for averaging or verification of the determined S-parameters.

Solving the S-parameter matrix of Eq. 1 for S₂₂ using Eqs. 6, 11, and 12 produces the following equation:

$${S}_{22} = \frac{( - 2 \cdot {Γ}_{1 open} + {Γ}_{2 short} \cdot {Γ}_{1 open} + {Γ}_{2 open} \cdot {Γ}_{1 open} + {Γ}_{2 open} - {Γ}_{2 short} )}{( - {Γ}_{2 short} \cdot {Γ}_{1 open} + {Γ}_{2 open} \cdot {Γ}_{1 open} - 2 + {Γ}_{2 short} + {Γ}_{2 open} )} \qquad Eq . 14$$

Combining Eq. 11 and Eq. 12 produces the following:

$$\frac{{Γ}_{2 short} - {S}_{11}}{{Γ}_{1 open} - {S}_{22}} = \frac{- ( 1 - {S}_{11} )}{1 + {S}_{22}} \qquad Eq . 15$$

Solving Eq. 15 for S₁₁ produces the following:

$${S}_{11} = \frac{( {Γ}_{2 short} + {Γ}_{2 short} \cdot {S}_{22} + {Γ}_{1 open} - {S}_{22} )}{( {Γ}_{1 open} + 1 )} \qquad Eq . 16$$

Substituting Eq. 14 into Eq. 16 produces Eq. 17, as follows:

$${S}_{11} = \frac{( - {Γ}_{2 short} \cdot {Γ}_{1 open} + {Γ}_{2 open} \cdot {Γ}_{1 open} - {Γ}_{2 short} + 2 \cdot {Γ}_{2 short} \cdot {Γ}_{2 open} - {Γ}_{2 open} )}{( - {Γ}_{2 short} \cdot {Γ}_{1 open} + {Γ}_{2 open} \cdot {Γ}_{1 open} - 2 + {Γ}_{2 short} + {Γ}_{2 open} )}$$

Because the DUT 12 is a passive two-port network (e.g., S₁₂=S₂₁), Eq. 12 can be rewritten as follows:

$${Γ}_{1 open} - {S}_{22} = \frac{{( {S}_{12} )}^{2}}{( 1 - {S}_{11} )} \qquad Eq . 18$$

Eq. 18 can be solved for S12 to produce the following:
S₁₂=(Γ₁ₒₚₑₙ−S₁₁·Γ₁ₒₚₑₙ−S₂₂+S₁₁·S₂₂)^{1/2} Eq. 19

Substituting equations 14 and 17 into equation 19 for S₂₂ and S₁₁, respectively, produces Eq. 20 as follows:

$${S}_{12} = {S}_{21} = \sqrt{2} \cdot {[ - ( {Γ}_{2 short} - 1 ) \cdot ( {Γ}_{1 open}^{2} - 1 ) \cdot \frac{( {Γ}_{2 short} - {Γ}_{2 short} \cdot {Γ}_{2 open} + {Γ}_{2 open}^{2} - {Γ}_{2 open} )}{{( - {Γ}_{2 short} \cdot {Γ}_{1 open} + {Γ}_{2 open} \cdot {Γ}_{1 open} - 2 + {Γ}_{2 short} + {Γ}_{2 open} )}^{2}} ]}^{1 / 2}$$

In view of the above example derivation, it is demonstrated that selected equations (e.g., Eqs. 14, 17, and 20) can thus be employed to determine the S-parameters S₁₁, S₁₂, S₂₁, and S₂₂ of the DUT 12 based on single port waveform parameter measurements at the respective ports P1 and P2. The determined S-parameters in turn can be used to construct the S-parameter matrix of Eq. 1.

FIG. 2 illustrates a system 20 for determining the S-parameters of the DUT 12 that can be implemented in accordance with an aspect of the present invention. The system 20 is operative to measure waveform parameters at a single port, such as at the input port P1 or at the output port P2, according to an embodiment of the present invention. In the configuration of the system 20 shown in FIG. 2, the DUT 12 is operatively connected with the source 14, which supplies an input signal V₁ to the input port P1 of the DUT. A network analyzer 22 is electrically connected with the input port P1 of the DUT 12 by an electrical connection means, such as a probe, schematically indicated at 24.

Those skilled in the art will appreciate that various types and configurations of probes exist, and that any such probe can be employed, such depending on the type and configuration of the DUT 12. The source 14 could be separate from the network analyzer 22, as shown in FIG. 2, or it could be integrated with or otherwise included in the network analyzer. As mentioned above, measurements typically are taken ports P1 and P2 simultaneously with a pair of probes. Alignment of the probes at such ports generally requires a high degree of precision. By employing the approach described herein to determine S-parameters, the physical measurements with the probe 24 can be facilitated since separate measurements can be made at the ports P1 and P2, such as within one or more probes.

An S-parameter calculator 30 is operatively associated with the network analyzer 22. The S-parameter calculator 30 is programmed and/or configured to ascertain S-parameters for the DUT 12 based on a subset of possible reflection coefficients derived from single port measurements at ports P1 and P2. For example, the S-parameter calculator 30 can compute the S-parameters by implementing selected equations (e.g., as listed above) based on values measured or otherwise obtained by the network analyzer 22.

The calculator 30 can be implemented as computer executable instructions within the network analyzer 22 or in an associated computer or analysis tool. The S-parameter calculator 30, for example, may take the form of a host computer, such as a PC, or a portion of the network analyzer dedicated to performing S-parameter calculations based on the measured values. Additionally, the S-parameter calculator 30 could even be embodied as manual calculations of the S-parameters based on the values measured by the network analyzer 22.

In an initial configuration of the system 20 shown in the example of FIG. 2, the output port P2 is left open, such that V₂ₘ=V₂ₚ. In this configuration, the network analyzer 22 can measure V₁ₘ and V₁ₚ at the input port P1 via the probe 24. The S-parameter calculator 30 can determine the reflection coefficient Γ₂ₒₚₑₙ (e.g., via implementation of Eq. 6) based on V₁ₘ and V₁ₚ determined from the single port measurement at port P1 while P2 is open.

The system 20 of FIG. 2 can then be re-configured such that the output port P2 is shorted, such that V₂ₘ=−V₂ₚ. The shorting of the output port P2 is achieved via electric coupling means, indicated schematically at 26 in FIG. 2 as dashed lines. The coupling means 26 may be any suitable electrically conductive device or member for shorting the terminals at the output port P2. The means 26 could, for example, be a piece of metal foil (e.g., copper or aluminum) used to short the terminals of the output port P2.

When the output port P2 is shorted, the network analyzer 22 can measure V₁ₘ and V₁ₚ at the input port P1 via the probe 24. The S-parameter calculator 30 can determine the reflection coefficient Γ₂ₛₕₒᵣₜ (e.g., via implementation of Eq. 11) based on the single port measurement at port P1 while P2 is shorted.

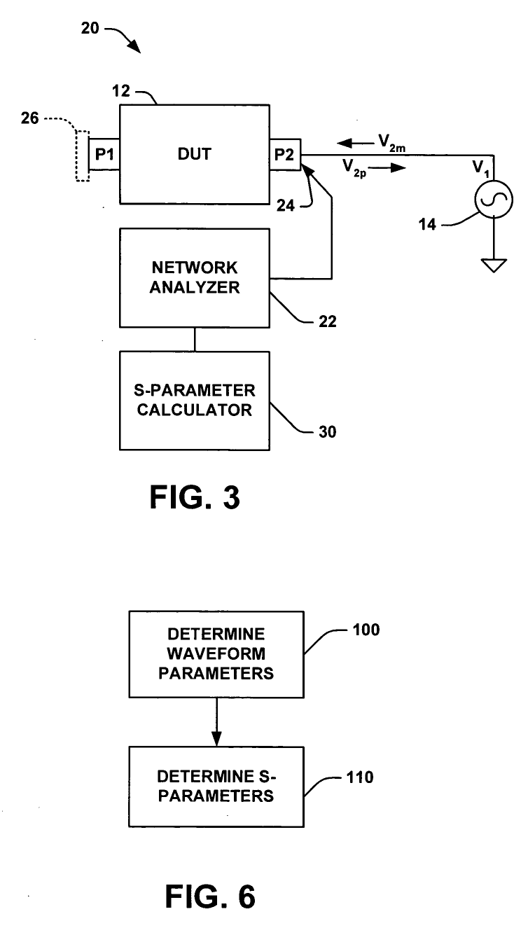

FIG. 3 illustrates the system 20 re-configured to enable single port measurements at port P2 according to an aspect of the present invention. In the example 20 of FIG. 3, the output port P2 of the DUT 12 is operatively connected with a source 14 that provides an input signal, indicated at V₂. The network analyzer 22 is connected with the output port P2 of the DUT 12 via the probe 24. The probe 24 can be the same or a different probe than utilized to perform measurements of the port P1. The input port P1 is then left open and, therefore, V₂ₘ=V₂ₚ. In this configuration, the network analyzer 22 can measure V₂ₘ and/or V₂ₚ at the output port P2 via the probe 24. The S-parameter calculator 30 can employ these measured parameters V₂ₘ and V₂ₚ to determine the reflection coefficient Γ₁ₒₚₑₙ (e.g., via implementation of Eq. 12).

The arrangement of the system 20 of FIG. 3 also can be re-configured to short terminals at the input port P1 via an electrical coupling means, which can be the same or different from the electrical coupling means 26 utilized to short P1. With P1 shorted, the above mathematical discussion provides that V₁ₘ=−V₁ₚ. When the input port P1 is shorted, the network analyzer 22 can measure V₂ₘ and/or V₂ₚ at the output port P2 via the probe 24. The S-parameter calculator 30 can employ these measurements to determine the reflection coefficient Γ₁ₛₕₒᵣₜ (e.g., via implementation of Eq. 13).

Additionally, the S-parameter calculator 30 can be programmed and/or configured to compute or otherwise determine the S-parameters S₁₁, S₁₂, S₂ₗ , and S₂₂ of the DUT 12 based on at least a subset of the single port measurements identified with respect to FIGS. 2 and 3. For instance, the S-parameter calculator 30 can employ Eqs. 14, 17, and 20 to determine reflection coefficients Γ₁ₒₚₑₙ, ₁ₛₕₒᵣₜ, Γ₂ₒₚₑₙ and _{Γ2short}. Either the network analyzer 22 or the S-parameter calculator 30 further can determine the reflection coefficients Γ₁ₒₚₑₙ, Γ₁ₛₕₒᵣₜ, Γ₂ₒₚₑₙ, and Γ₂ₛₕₒᵣₜ sufficient for enabling a determination of the S-parameters.

It is to be understood and appreciated that, since the reflection coefficients Γ vary as a function of the waveform parameters, equations employed to define the S-parameters (e.g., Eqs. 14, 17, and 20) could be rewritten in terms of the measured waveform parameters instead of reflection coefficients. As a result, the S-parameters could be determined directly as functions of the measured waveform parameters, without explicitly determining the reflection coefficients.

In view of the above embodiments of FIGS. 2 and 3, the present invention thus enables S-parameters to be determined through single port wave parameter measurements at the input port P1 and output port P2 of the DUT 12. The system 20 also permits the determination of the S-parameters of the DUT 12 without requiring the use of a load connected at the port opposite the source 14. Additionally, the opened and shorted conditions at the respective of the ports P1 and P2, can be readily achieved with a high degree of reliability, while avoiding difficulties that may be associated with obtaining multi-port measurements, such as establishing probe contacts simultaneously with multiple ports of the DUT 12. Additionally, a calibration procedure for a network analyzer can be significantly simplified since the present invention does not require the use of matched loads when measuring waveform parameters.

To this point, the present invention has been described mostly in terms of determining S-parameters of a two-port network. It will be appreciated, however, that the system and methodology of the present invention could be implemented to determine the S-parameters of a network having more than two ports. This is because, in a multi-port network where the forward and reverse gain S-parameters are equal, equations for determining the reflection coefficients and thus the S-parameters of the network may be determined. While the determination of such equations may involve complex algebraic and other mathematical operations, the equations are nonetheless ascertainable based on the teachings contained herein.

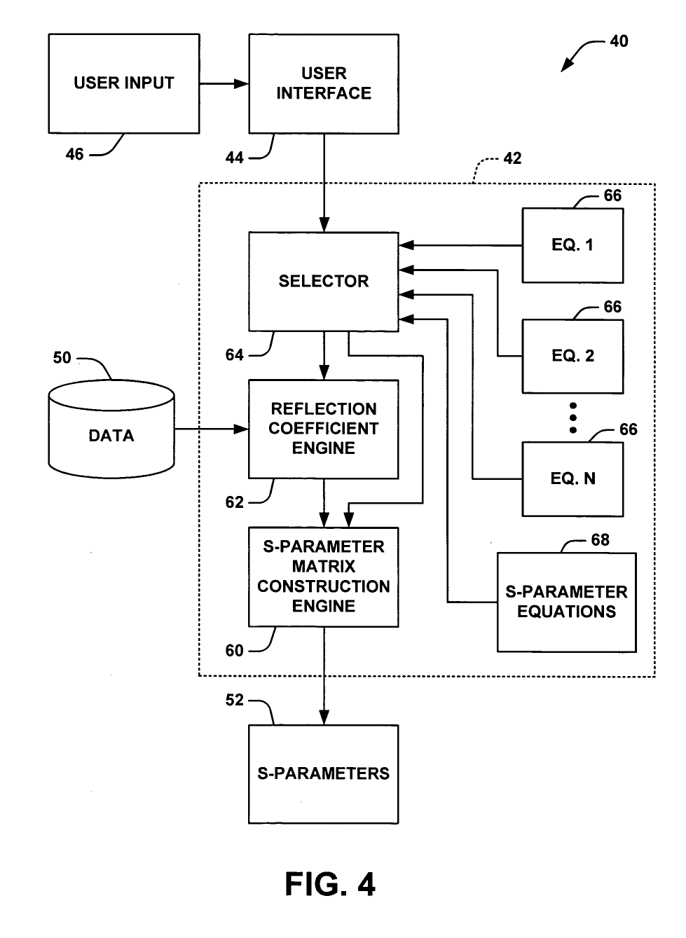

FIG. 4 illustrates a system 40 for determining S-parameters according to an aspect of the present invention. The system 40 includes an S-parameter calculator 42 that implements an algorithm (e.g., equations) for determining reflection coefficients and S-parameters of a DUT. The S-parameter calculator 42 can be implemented as computer executable instructions, for example, running in a computer, workstation, network analyzer or other test equipment. The system 40 can also include a user interface 44 associated with the S-parameter calculator 42, such as a graphical user interface (GUI). The user interface 44 provides a programmable mechanism to receive user inputs 46 for establishing operating parameters associated with the S-parameter calculator 42. For example, the user inputs 46 can define structural and/or functional characteristics associated with a DUT for which S-parameters are to be determined. The user inputs can also establish procedures for implementing verification of the S-parameter results.

The S-parameter calculator 42 is operatively connected to a source of data 50, which includes measurement information for a multi-port network. For example, the data 50 includes measurement data (e.g., measured waveform parameters) based on which reflection coefficients can be computed for the multi-port network. The data 50 can be stored in a computer-readable medium, such as a volatile storage device (e.g., RAM, DRAM etc.) or a non-volatile storage device (e.g., a hard disk drive, CD-ROM, etc.). The data can be provided in real time, such as by measurements implemented by a network analyzer or, alternatively, it can be stored for subsequent processing by the S-parameter calculator 42. The S-parameter calculator 42 is operative to construct an S-parameter matrix for the DUT and provide an indication of S-parameters, indicated as 52, based on the measurement data 50.

The S-parameter calculator 42 includes an S-parameter matrix construction engine 60 and a reflection coefficient engine 62. The S-parameter calculator 42 also includes a selector 64 for selecting parameters that define the operations to be performed by the reflection coefficient engine 62. The selector 64 may also select parameters that define the operation of the matrix construction engine 60. For instance, the selector 64 can select an appropriate set of equations 66 based on the user input 46 provided by to user interface 44. The selector 64, for example, may be operable to select from a set of available equations 66, such as those described above (e.g., Eqs. 6, 11, 12, and 13), for determining reflection coefficients of the DUT based on the data 50. Additionally or alternatively, the selector can select appropriate equations from an available set of equations 68 for computing the S-parameters. For example, the equations 66 and 68 can be stored as a library of predetermined equations from which the selector 64 can access necessary equations based on the user inputs 46.

By way of further example, as shown in FIG. 4, the selector 64 may access a number (1, 2, . . . N) of reflection coefficient equations 66 to provide to the reflection coefficient engine 62. The number and type of reflection coefficient equations 66 provided to the reflection coefficient engine 62 may depend on a variety of factors, such as the number of ports of the DUT and/or the desired level of redundancy or verification that is to be performed in determining the S-parameters 52. For example, in regard to a two-port DUT, three of the four reflection coefficient equations (e.g., Eqs. 6, 11, 12, and 13) will be sufficient to determine the four S-parameters.

A more conservative approach for a two-port network, can employ four of reflection coefficient equations 66 (e.g., Eqs. 6, 11, 12, and 13) to provide multiple sets of S-parameters, which can be correlated or compared to provide error checking and/or averaging. The equation selector 64 may also be operable to select other equations 68, such as those described above (e.g., Eqs. 14, 17, and 20), for determining the S-parameters 52 based on the computed reflection coefficients. The matrix construction engine 60 thus computes the S-parameters based on applying the selected set of equations 66 and 68 to the measurement data 50.

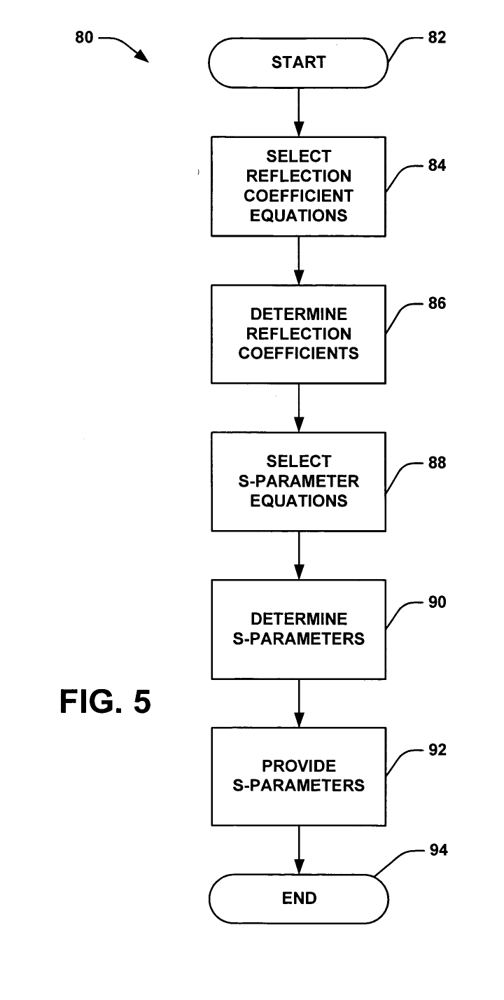

In view of the foregoing structural and functional features described above, a methodology 80 for determining the S-parameters of the DUT 12, in accordance with an embodiment of the present invention, will be better appreciated with reference to FIG. 5. While, for purposes of simplicity of explanation, the methodology 80 of FIG. 5 is shown and described as being implemented serially, it is to be understood and appreciated that the present invention is not limited to the illustrated order, as some aspects could, in accordance with the present invention, occur in different orders and/or concurrently with other aspects from that shown and described. Moreover, not all illustrated features may be required to implement the methodology 80 in accordance with an aspect of the present invention. It is to be further understood that the methodology 80 can be implemented in hardware, software (e.g., as computer-executable instructions running in computer or test equipment), manually, or any combination thereof.

The methodology 80 begins at 82. This can include defining attributes of a DUT (e.g., number of ports, the types and quantities of measurements, etc.). This can result in initializing variables to their starting values and instantiating objects in associated software. At 84, reflection coefficients equations are selected. For a two port network, for example, the reflection coefficients can include Γ₁ₒₚₑₙ, Γ₁ₛₕₒᵣₜ, Γ₂ₒₚₑₙ, Γ₂ₛₕₒᵣₜ. The reflection coefficients are selected for use in the determination of the S-parameters of a DUT (e.g., the DUT 12 of FIG. 1). As described above, different numbers of reflection coefficient equations can be selected, depending on factors such as the number of ports of the DUT and the desired level of averaging and/or verification of the computations. For example, in a two-port DUT, equations for determining reflection coefficients Γ₁ₒₚₑₙ, Γ₂ₒₚₑₙ, and Γ₂ₛₕₒᵣₜ can be used to determine the S-parameters of the DUT, without any verification or averaging. If verification or averaging of the S-parameters is desired for improved accuracy, an equation for determining the Γ₁ₛₕₒᵣₜ reflection coefficient may also be selected for the two-port example.

At 86, the reflection coefficients are determined based on the equations selected at 84 using the waveform parameters, such as described above. Alternatively, at 86, all or a selected number of reflection coefficients could be determined based on the waveform parameters available to the system without requiring selection. For example, in determining reflection coefficients for the two-port DUT described above, if waveform parameters sufficient to determine reflection coefficients Γ₁ₒₚₑₙ, Γ₁ₛₕₒᵣₜ, Γ₂ₒₚₑₙ, and Γ₂ₛₕₒᵣₜ are available, all four of these reflection coefficients can be determined at 86. If, however, a subset of waveform parameters sufficient to determine only three reflection coefficients are available, then only three reflection coefficients may be determined at 86.

At 88, S-parameter equations are selected. The S-parameter equations enable S-parameters (e.g., S₁₁, S₁₂, S₂₁, S₂₂) of the DUT to be determined. As described above, the S-parameters may be determined through a variety of equations that incorporate different combinations of the reflection coefficients, such as determined at 86. Thus, the number of S-parameter equations selected may vary, depending on factors such as the number of ports of the DUT and the available reflection coefficients, as determined at 86.

At 90, the S-parameters are determined based on the equations selected at 88. Alternatively, the S-parameters could be determined at 90 without requiring selection of S-parameter equations at 88, such as accessing appropriate equations automatically based on the reflection coefficients available methodology 80. For example, in determining S-parameters for a two-port DUT, such as described above, a subset of some or all S-parameter equations can be utilized, which can vary according to the available reflection coefficients. As a result, where more reflection coefficients than needed are available, the S-parameters can be determined at 90 to provide redundant verification of the results and/or averaging. In a situation where a subset of less than all available reflection coefficients exists, fewer available S-parameter equations can still be utilized to ascertain the full S-parameter matrix. At 92, the S-parameters (S₁₁, S₁₂, S₂₁, S₂₂) determined from the equations implemented at 90 are provided. The S-parameters further can be provided at 92 after performing a comparison of the S-parameters that may have been computed based on different sets of reflection coefficients. This comparison can be utilized to provide an indication of the accuracy of the results. The methodology then ends at 94.

FIG. 6 depicts a method for determining S-parameters of a network. The method includes determining waveform parameters based on single port measurements performed at plural ports of the network, as shown at 100. The method also includes determining S-parameters of the network based on the waveform parameters, as shown at 110.

What have been described above are examples of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications and variations that fall within the spirit and scope of the appended claims.

1. A system for determining S-parameters of a network, comprising:
an S-parameter calculator that computes the S-parameters of the network based on waveform parameters determined based on single port measurements implemented at each of plural ports of the network.

2. The system of claim 1, the waveform parameters comprise information related to at least one of a transmission and a reflection of a signal provided at the single port.

3. The system of claim 1, the S-parameter calculator determines reflection coefficients based on the waveform parameters, the S-parameter calculator determining the S-parameters based on the reflection coefficients.

4. The system of claim 3, the reflection coefficients comprise values functionally related to a transmission and a reflection of a signal provided at the single port.

5. The system of claim 1, the network is a two-port network comprising first and second ports, the single port measurements comprising measurements implemented at at least three of:
the first port while the second port is open;
the first port while the second port is shorted;
the second port while the first port is open; and
the second port while the first port is shorted.

6. The system of claim 1, the S-parameter calculator determines reflection coefficients based on waveform parameters, the reflection coefficients comprising at least three of:
a first reflection coefficient of a first port while each of the other plural ports is open;
a second reflection coefficient of the first port while each of the other plural ports is shorted;
a third reflection coefficient of a second port while each of the other plural ports is open; and
a fourth reflection coefficient of the second port while each of the other plural ports is shorted.

7. The system of claim 1, the S-parameter calculator computes the S-parameters of the network based on a subset of less than all possible reflection coefficients for the network.

8. The system of claim 1, further comprising a network analyzer for performing the single port measurements.

9. The system of claim 1, the network is a passive multi-port network.

10. A system for determining S-parameters of an n-port network, n being a positive integer, the system comprising:
a reflection coefficient engine that provides a subset of at least n-1 reflection coefficients associated with ports of the multi-port network; and
an S-parameter calculator that computes the S-parameters for the n-port network based on the subset of reflection coefficients.

11. The system of claim 10, the reflection coefficient engine provides the subset of reflection coefficients based on single port measurements performed at each of the ports of the n-port network.

12. The system of claim 11, n equals two, such that the n-port network includes first and second ports, the single port measurements comprising measurements implemented at at least three of:
the first port while the second port is open;
the first port while the second port is shorted;
the second port while the first port is open; and
the second port while the first port is shorted.

13. The system of claim 10, the set of reflection coefficients comprising a subset of less than all possible reflection coefficients for the network.

14. A system for determining S-parameters of a network, the system comprising:
means for determining at least one of waveform parameters and reflection coefficients based on single port measurements of the network; and
means for computing S-parameters of the network based on the at least one of waveform parameters and reflection coefficients.

15. The system of claim 14, further comprising means for performing single port measurements to enable a determination of the at least one of waveform parameters and reflection coefficients, the determining means computes the at least one of waveform parameters and reflection coefficients based on the single port measurements.

16. The system of claim 14, further comprising means for selecting a set of the reflection coefficients to be implemented by the determining means.

17. The system of claim 16, the set of reflection coefficients comprising a subset of less than all possible reflection coefficients for the network.

18. The system of claim 14, wherein the computing means comprises means for determining plural sets of the S-parameters for the network based on different respective sets of the reflection coefficients.

19. The system of claim 18, wherein the computing means comprises means for averaging determined S-parameters for at least some of the plural sets of S-parameters.

20. A method for determining S-parameters of a network comprising the steps of:
determining waveform parameters based on single port measurements performed at plural ports of the network; and
determining S-parameters of the network based on the waveform parameters.

21. The method of claim 20, the determination of S-parameters further comprises:
determining reflection coefficients based on the waveform parameters; and
determining the S-parameters based on the reflection coefficients.

22. The method of claim 20, further comprising implementing single port measurements at each of the plural ports to provide the signal port measurements.

23. The method of claim 22, the network comprising a two-port network having first and second ports, the measurement of waveform parameters comprising at least three of:
measuring waveform parameters at the first port while the second port is open;
measuring waveform parameters at the first port while the second port is shorted;
measuring waveform parameters at the second port while the first port is open; and
measuring waveform parameters at the second port while the first port is shorted.

24. The method of claim 20, the network comprising a two-port network having first and second ports, the determination of S-parameters further comprising at least three of:
determining a first reflection coefficient of the first port while the second port is open;
determining a second reflection coefficient of the first port while the second port is shorted;
determining a third reflection coefficient of the second port while the first port is open; and
determining a fourth reflection coefficient of the second port while the first port is shorted.

25. The method of claim 20, the determination of S-parameters comprises:
selecting equations for determining reflection coefficients;
implementing the selected equations to determine a subset of reflection coefficients for the network based on the waveform parameters; and
determining the S-parameters based on the reflection coefficients.

26. The method of claim 20, the determination of S-parameters comprises using different S-parameter equations to determine a plurality of values for the same S-parameter and averaging the plurality of values.

27. The method of claim 19, the step of determining S-parameters comprises using different S-parameter equations to determine a plurality of values for the same S-parameter and comparing the values to facilitate verifying accuracy of the S-parmeters.

28. A computer-readable medium having computer-executable instructions for performing a method comprising:
receiving waveform parameters based on single port measurements performed at plural ports of the network; and
determining S-parameters of the network based on the waveform parameters.

29. A computer-readable medium having computer-executable instructions for performing a method comprising:
determining reflection coefficients based on single port measurements performed at plural ports of the network; and
determining S-parameters of the network based on the reflection coefficients.
